(19) United States
(12) Patent Application Publication
(10) Pub. No.: US 2013/0214796 A1
(43) Pub. Date: Aug. 22, 2013

(54) DETERIORATION DETECTION CIRCUIT, SEMICONDUCTOR INTEGRATED DEVICE, AND DETERIORATION DETECTION METHOD

(71) Applicant: NEC CORPORATION, (US)

(72) Inventor: Kohei UCHIDA, Tokyo (JP)

(73) Assignee: NEC CORPORATION, Tokyo (JP)

(21) Appl. No.: 13/764,298

(22) Filed: Feb. 11, 2013

(30) Foreign Application Priority Data
Feb. 16, 2012 (JP) 2012-031844

(51) Int. Cl. G01R 31/3193

(52) U.S. Cl. CPC G01R 31/31937
USPC 324/617

(57) ABSTRACT

A deterioration detection circuit according to the present invention includes a deterioration sensor measuring a deterioration amount of a semiconductor integrated circuit, a differentiator calculating a time differential value of the deterioration amount measured by the deterioration sensor; and a first notification circuit comparing the time differential value with a first threshold value and outputting a first alarm depending on the result of the comparison.

This application is based upon and claims the benefit of priority from Japanese Patent Application No. 2012-031844, filed on Feb. 16, 2012, the disclosure of which is incorporated herein in its entirety by reference.

### TECHNICAL FIELD

The present invention relates to a technology for detecting deterioration of a semiconductor integrated circuit.

### BACKGROUND ART

While a silicon-based LSI (Large Scale Integration) operates, the delay of a transmission signal in the LSI is gradually degraded and deteriorated by an influence of a hot carrier, NBTI (Negative Bias temperature Instability), or the like. Previously, a method is used as a countermeasure to the aged deterioration, in which an amount of delay of a transmission signal in the LSI after a period of a device use is predicted based on the period of LSI use, only the LSI having a margin in the delay against the amount of delay after the period of use is selected and used in the device, and the device using the selected LSI is delivered.

In recent years, a deterioration sensor for measuring an amount of deterioration of the LSI has been developed, the deterioration sensor is mounted in a semiconductor device, and the amount of deterioration of the LSI is monitored by the deterioration sensor.

For example, a semiconductor integrated circuit which has a deterioration diagnosis circuit for predicting the time of fault of a real circuit in the semiconductor integrated circuit due to aged deterioration is disclosed in Japanese Patent Application Laid-Open No. 2008-147245 (hereinafter, referred to as patent literature 1).

To be more specific, the patent literature 1 discloses a technology in which a pulse signal is transmitted through a deterioration diagnostic target circuit that is provided around the same time with the real circuit, a timing of a clock signal whose rising edge is delayed by a predetermined time from a rising edge of the pulse signal and whose frequency is the same as that of the pulse signal is compared with a timing of the pulse signal passed through the deterioration diagnostic target circuit and then, it is determined whether or not the deterioration occurs in the deterioration diagnostic target circuit based on the result of the comparison, and furthermore, a possibility of deterioration of the real circuit is predicted (paragraphs [0045] to [0047] of patent literature 1).

That is to say, this technology uses the difference between the timing of the pulse signal passed through the deterioration diagnostic target circuit and the timing of the clock signal as an amount of deterioration.

### SUMMARY

An exemplary of an object of the present invention is to detect deterioration of an LSI in a semiconductor device before fatal deterioration occurs.

A deterioration detection circuit according to an exemplary aspect of the present invention includes a deterioration sensor for measuring an amount of deterioration of a semiconductor integrated circuit, a differentiator for calculating a time differential value of the amount of deterioration measured by the deterioration sensor, and a first notification circuit for comparing the time differential value with a first threshold value and outputting a first alarm according to the result of the comparison.

A semiconductor device according to an exemplary aspect of the present invention includes a deterioration detection circuit including a deterioration sensor for measuring an amount of deterioration of a semiconductor integrated circuit, a differentiator for calculating a time differential value of the amount of deterioration measured by the deterioration sensor, and a first notification circuit for comparing the time differential value with a first threshold value and outputting a first alarm according to the result of the comparison.

A deterioration detection method according to an exemplary aspect of the present invention includes the steps of (A) measuring an amount of deterioration of a semiconductor integrated circuit, (B) calculating a time differential value of the amount of deterioration, and (C) comparing the time differential value calculated in the step (B) with a first threshold value, and outputting a first alarm according to the result of the comparison.

### BRIEF DESCRIPTION OF THE DRAWINGS

Exemplary features and advantages of the present invention will become apparent from the following detailed description when taken with the accompanying drawings in which:

FIG. 1 is a block diagram showing a configuration of the semiconductor device according to the first exemplary embodiment;

FIG. 2 is a figure for explaining the operation of the deterioration detection circuit in a semiconductor device shown in FIG. 1;

FIG. 3 is a block diagram showing a configuration of the semiconductor device according to the second exemplary embodiment;

FIG. 4 is a figure for explaining the operation of the deterioration detection circuit in a semiconductor device shown in FIG. 3; and

FIG. 5 is a block diagram showing a configuration of the semiconductor device according to the third exemplary embodiment.

### EXEMPLARY EMBODIMENT

Hereinafter, exemplary embodiments will be described in detail by using drawings. The same reference number represents an element having the same function or a corresponding function in the drawings.

### First Exemplary Embodiment

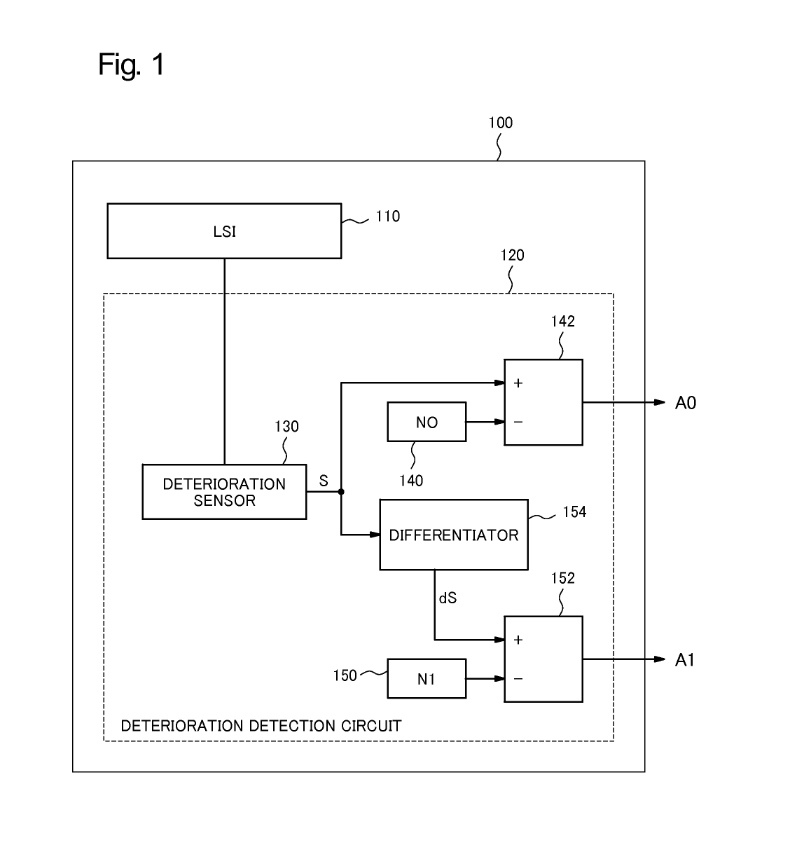

FIG. 1 shows a semiconductor device 100 according to the first exemplary embodiment. The semiconductor device 100 includes an LSI 110 and a deterioration detection circuit 120 which detects the deterioration of the LSI 110 and alerts it to the outside the semiconductor device 100.

The deterioration detection circuit 120 includes a deterioration sensor 130, a threshold value storage circuit 140, a deterioration error notification circuit 142, a threshold value storage circuit 150, a first notification circuit 152, and a differentiator 154.

The deterioration sensor 130 detects an amount S of deterioration of the LSI 110 and outputs it to the deterioration error notification circuit 142 and the differentiator 154. It is possible to use any kind of deterioration sensors known conventionally which measure the amount of deterioration of the semiconductor integrated circuit, for the deterioration sensors 130. It is possible for the deterioration sensor 130 to measure another amount of deterioration, such as an amount of delay time or the like, instead of the amount S of deterioration.

The threshold value storage circuit 140 is a storage element such as a register or the like and stores a threshold value N0 that is set to the deterioration amount S in advance (hereinafter, referred to as a deterioration amount threshold value).

The deterioration error notification circuit 142 is a comparator, which compares the deterioration amount S measured by the deterioration sensor 130 with the deterioration amount threshold value N0 stored in the threshold value storage circuit 140, and outputs an alarm A0 indicating an error when the deterioration amount S is equal to or greater than the deterioration amount threshold value N0. Hereinafter, the alarm A0 is referred to as a “deterioration alarm”.

The differentiator 154 calculates a time differential value (hereinafter, referred to as a deterioration amount differential value dS) of the deterioration amount S measured by the deterioration sensor 130 and outputs it to the first notification circuit 152.

The threshold value storage circuit 150 is a storage element such as a register or the like and stores a threshold value N1 (hereinafter, referred to as a first threshold value) which is set to the deterioration amount differential value dS in advance.

The first notification circuit 152 is a comparator, which compares the deterioration amount differential value dS obtained by the differentiator 154 with the first threshold value N1 stored in the threshold value storage circuit 150, and outputs a first alarm A1 indicating an error when the deterioration amount differential value dS becomes equal to the first threshold value N1.

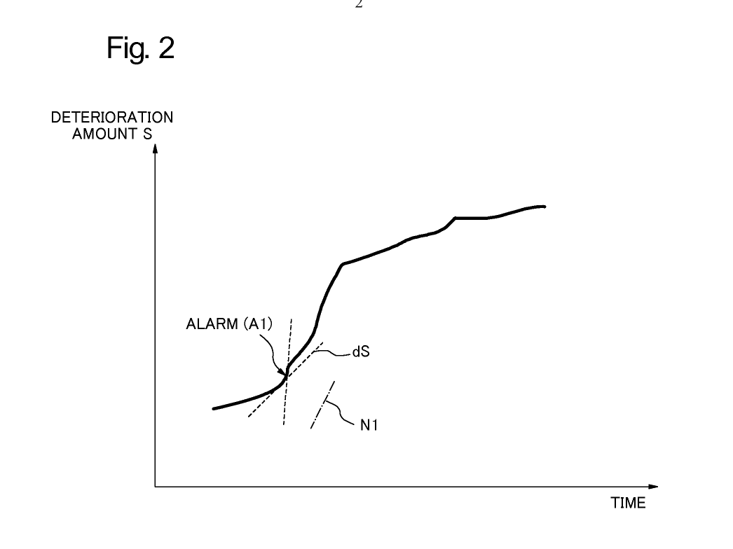

FIG. 2 is a figure for explaining the principle that the first notification circuit 152 and the differentiator 154 output the first alarm A1. As shown in FIG. 2, if the deterioration amount differential value dS obtained by the differentiator 154 is equal to or greater than the first threshold value N1, the first alarm A1 is outputted from the first notification circuit 152.

Thus, in the semiconductor device 100 according to the present exemplary embodiment, the deterioration detection circuit 120 further outputs the first alarm A1 indicating that the time differential value of the deterioration amount S becomes equal to the first threshold value N1 in addition to the deterioration alarm A0 indicating that the deterioration amount S becomes equal to the deterioration amount threshold value N0. Therefore, it is possible to alert the outside when increasing the rate of deterioration due to unforeseen circumstances and maintain the LSI 110 in good condition before fatal deterioration occurs.

### Second Exemplary Embodiment

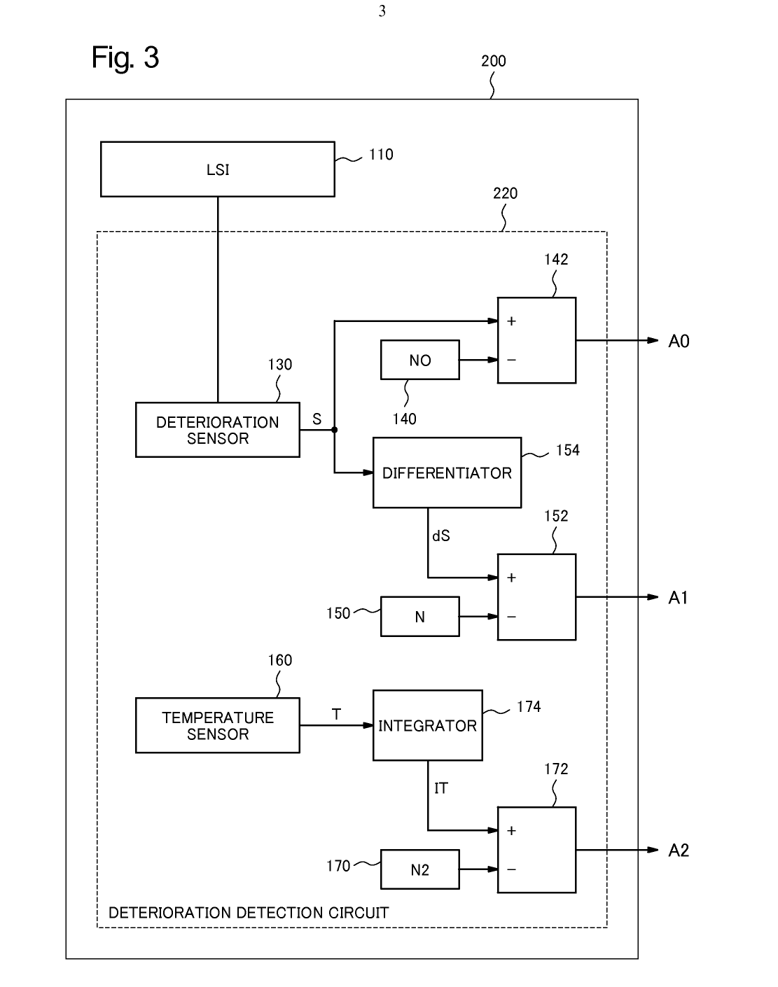

FIG. 3 shows a semiconductor device 200 according to a second exemplary embodiment. The semiconductor device 200 includes the LSI 110 and a deterioration detection circuit 220.

The different point of the deterioration detection circuit 220 from the deterioration detection circuit 120 in the semiconductor device 100 shown in FIG. 1 is that the deterioration detection circuit 220 further includes a temperature sensor 160, a threshold value storage circuit 170, an integrator 174, and a second notification circuit 172. Therefore, it is decided to explain mainly the temperature sensor 160, the threshold value storage circuit 170, the integrator 174, and the second notification circuit 172.

The temperature sensor 160 measures a temperature T and outputs it to the integrator 174.

The integrator 174 calculates a time integral value IT of the temperature T measured by the temperature sensor 160 (hereinafter, referred to as a temperature integral value).

The threshold value storage circuit 170 is a storage element such as a register or the like and stores a threshold value N2 that is set to the temperature integral value IT in advance (hereinafter, referred to as a second threshold value).

The second notification circuit 172 is a comparator, which compares the temperature integral value IT obtained by the integrator 174 with the second threshold value N2 stored in the threshold value storage circuit 170, and outputs a second alarm A2 indicating an error when the temperature integral value IT becomes equal to or greater than the second threshold value N2.

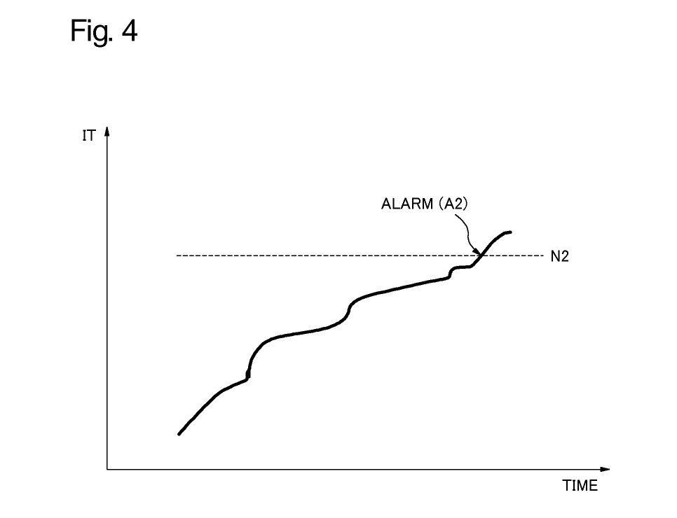

FIG. 4 is a figure for explaining the principle that the second notification circuit 172 and the integrator 174 output the second alarm A2. As shown in FIG. 4, when the temperature integral value IT obtained by the integrator 174 becomes equal to or greater than the second threshold value N2, the second alarm A2 is outputted from the second notification circuit 172.

Namely, in the semiconductor device 200 of the present exemplary embodiment, the deterioration detection circuit 220 further outputs the second alarm A2 based on the temperature integral value IT in addition to the deterioration alarm A0 and the first alarm A1.

Since a deterioration of a silicon semiconductor is exponentially proportional to temperature, the deterioration amount would be changed by one order if the operating temperature changes. Therefore, the deterioration detection circuit 220 of the semiconductor device 200 according to the present exemplary embodiment further monitors the temperature integral value IT and outputs the second alarm A2 based on the result of the monitoring. As a result, it is also possible to notify outside of the situation of deterioration of the LSI 110 from the aspect of temperature.

### Third Exemplary Embodiment

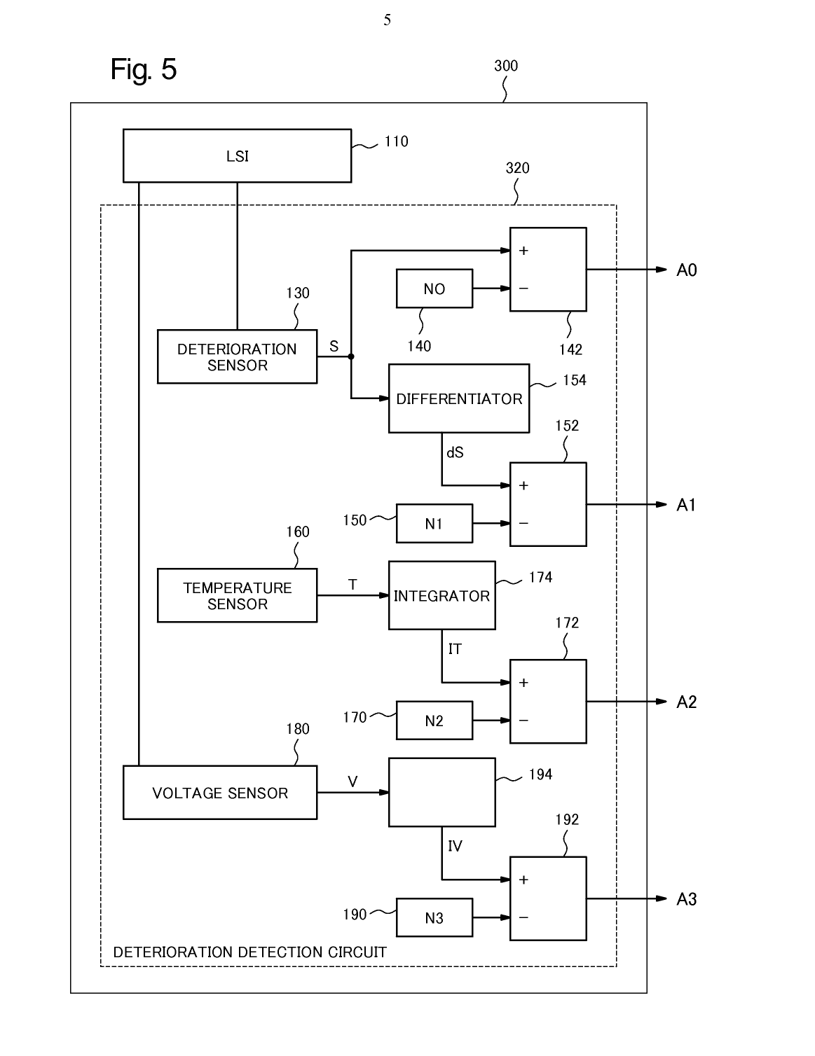

FIG. 5 shows a semiconductor device 300 according to a third exemplary embodiment. The semiconductor device 300 includes the LSI 110 and a deterioration detection circuit 320.

The different point of the deterioration detection circuit 320 from the deterioration detection circuit 220 in the semiconductor device 200 shown in FIG. 3 is that the deterioration detection circuit 320 further includes a voltage sensor 180, a threshold value storage circuit 190, an integrator 194, and a third notification circuit 192 Therefore, it is decided to explain mainly the voltage sensor 180, the threshold value storage circuit 190, the integrator 194, and the third notification circuit 192.

The voltage sensor 180 measures a voltage V at a predetermined measurement point in the LSI 110 and outputs it to the integrator 194.

The integrator 194 calculates a time integral value IV of the voltage V measured by the voltage sensor 180 (hereinafter, referred to as a voltage integral value).

The threshold value storage circuit 190 is a storage element such as a register or the like and stores a threshold value N3 that is set to the voltage integral value IV in advance (hereinafter, referred to as a third threshold value).

The third notification circuit 192 is a comparator, which compares the voltage integral value IV obtained by the integrator 194 with the third threshold value N3 stored in the threshold value storage circuit 190, and outputs a third alarm A3 indicating an error when the voltage integral value IV becomes equal to or greater than the third threshold value N3.

Namely, in the semiconductor device 300 of the present exemplary embodiment, the semiconductor device 300 further outputs the third alarm A3 based on the voltage integral value IV in addition to the deterioration alarm A0, the first alarm A1, and the second alarm A2.

The deterioration of the semiconductor LSI has a strong correlation with a voltage. Therefore, the deterioration detection circuit 320 of the semiconductor device 300 according to the present exemplary embodiment monitors the voltage integral value IV and outputs the third alarm A3 based on the monitoring result. As a result, it is possible to notify the outside of the situation of deterioration of the LSI 110 from the aspect of voltage.

However, in the related art, the deterioration amount such as an amount of delay or the like is obtained by the deterioration sensor. The error is outputted based on the result of monitoring whether or not the deterioration amount exceeds a specified value.

But if the presence or absence of an error is judged only based on whether or not the deterioration amount exceeds the specified value, it is not possible to notify a user of the information about an acceleration of deterioration rate due to unforeseen circumstances before the deterioration amount exceeds the specified value.

Therefore, there is a risk that the LSI in the semiconductor device has been already deteriorated fatally when the error is outputted.

An exemplary advantage according to the invention is that it is possible to detect the deterioration of the LSI in the semiconductor device before it becomes fatal.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A deterioration detection circuit, comprising:
a deterioration sensor measuring a deterioration amount of a semiconductor integrated circuit;
a differentiator calculating a time differential value of the deterioration amount measured by the deterioration sensor; and
a first notification circuit comparing the time differential value with a first threshold value and outputting a first alarm depending on the result of the comparison.

2. The deterioration detection circuit according to claim 1, further comprising
a temperature sensor;
a temperature integrator calculating a time integral value of the temperature measured by the temperature sensor; and
a second notification circuit comparing the time integral value with a second threshold value and outputting a second alarm depending on the result of the comparison.

3. The deterioration detection circuit according to claim 1, further comprising
a voltage sensor measuring a voltage at a predetermined measurement point in the semiconductor integrated circuit;
a voltage integrator calculating a time integral value of the voltage measured by the voltage sensor; and
a third notification circuit comparing the time integral value with a third threshold value and outputting a third alarm depending on the result of the comparison.

4. A semiconductor integrated device, comprising
a deterioration detection circuit, wherein the deterioration detection circuit comprises
a deterioration sensor measuring a deterioration amount of a semiconductor integrated circuit;
a differentiator calculating a time differential value of the deterioration amount measured by the deterioration sensor; and
a first notification circuit comparing the time differential value with a first threshold vale and outputting a first alarm depending on the result of the comparison.

5. A deterioration detection method, comprising the steps of:
(A) measuring a deterioration amount of a semiconductor integrated circuit;
(B) calculating a time differential value of the deterioration amount; and
(C) comparing the time differential value with a first threshold value and outputting a first alarm depending on the result of the comparison.
